(19) United States
(12) Patent Application Publication
(10) Pub. No.: US 2024/0421782 A1
(43) Pub. Date: Dec. 19, 2024

(54) POWER AMPLIFIER

(71) Applicant: Mitsubishi Electric Corporation, Tokyo (JP)

(72) Inventors: Ko KANAYA, Tokyo (JP); Kazuya YAMAMOTO, Tokyo (JP)

(73) Assignee: Mitsubishi Electric Corporation, Tokyo (JP)

(21) Appl. No.: 18/698,371

(22) PCT Filed: Jan. 25, 2022
(86) PCT No.: PCT/JP2022/002698

§ 371 Date: Apr. 4, 2024

(51) Int. Cl. H03F 3/21

(52) U.S. Cl. CPC H03F 3/21; H03F 2200/451

(57) ABSTRACT

A power amplifier according to the present disclosure includes a transistor; a main line connected to a drain of the transistor; a branch line which branches from the main line and is connected to a drain pad; and a drain bias circuit which is provided on the branch line, wherein the drain bias circuit has a first shunt capacitor which is connected to the branch line and a second shunt capacitor which is connected to the branch line between the first shunt capacitor and the drain pad, the first shunt capacitor is capacitive at an operating frequency of the transistor, the second shunt capacitor is inductive at the operating frequency, and the first shunt capacitor and the second shunt capacitor resonate at the operating frequency.

### FIELD

The present disclosure relates to a power amplifier.

### BACKGROUND

PTL 1 discloses a power amplifier having plural amplification elements. A tournament-diagram-shaped circuit which has plural transmission lines in a shape of a tournament diagram is connected to the plural amplification elements. Plural difference frequency short circuits are connected by shunt connection with plural nodes of the tournament-diagram-shaped circuit.

Each of the plural difference frequency short circuits has an inductor and a capacitor which are connected in series. A resonance frequency of the plural difference frequency short circuits becomes lower as spaced further away from the plural amplification elements. The difference frequency short circuits having an equivalent resonance frequency are connected to plural nodes, which are in the same stages, among the plural nodes.

### CITATION LIST

### Patent Literature

[PTL 1] International Publication No. WO 2020/202532

### SUMMARY

### Technical Problem

Accompanying capacity enlargement in information communication, a high-frequency module used for a small Earth station for satellite communication has been shifting to the Ka band in which a wider band width than the Ku band can be used. In the Ku band, an internal matching FET (field effect transistor) is in general used for a final stage amplifier of a high-frequency module transmission circuit. However, it is difficult to apply the internal matching FET in the Ka band.

In the internal matching FET for the Ku band, a matching circuit is in general configured by utilizing wires for connecting a semiconductor transistor chip and a circuit substrate. Meanwhile, in the Ka band, a shorter wire than that for the Ku band is necessary. In general, a short wire suitable for the Ka band cannot physically connect a chip and a substrate. Even if connection can be made, a manufacturing tolerance cannot be ignored because a wire length is short in the Ka band. Thus. RF characteristics become sensitive about manufacturing variation in the wire length, and a manufacturing yield might thereby largely be lowered.

Thus, for example, an MMIC (monolithic microwave integrated circuit) is used for the final stage amplifier for the Ka band. In the MMIC, no wire is used in the matching circuit, and all circuit patterns are formed on a semiconductor chip.

Further, in order to further enlarge a transmission capacity, demands for multicarrier communication have been increasing in the Ku band. In such circumstances, there are cases where the internal matching FET used for the high-frequency module transmission circuit is requested to have specifications which conform to multicarrier communication. The specifications conforming to multicarrier communication mean low distortion characteristics in a wide detuning width. Distortion as a problem in a semiconductor amplifier for satellite communication is third order intermodulation distortion IMD3 (3rd intermodulation distortion) which in general occurs when two main signals are input. In general, a state where the ratios between the IMD3 and the main signal is −25 dBc or lower is used as a criterion.

Here, a difference between frequencies of the two main signals will be referred to as detuning frequency Δf. In detuning width specifications for Ku-band single-carrier communication. Δf=approximately 1 to 10 MHz, but in multicarrier communication, Δf=1 to 375 MHz, for example, and a wide detuning width is demanded. Note that a maximum value of Δf is ½ of the band width of a used band of 13.75 to 14.5 GHz, that is. (14.5 GHz−13.75 GHz)/2=375 MHz. Such demands for multicarrier communication have spread to the Ka band. Because the used band of the Ka band is 27.5 to 30 GHz, the maximum detuning width is Δf=(30 GHz−27.5 GHz)/2=1,250 MHz. In other words, a detuning width of three times or more Δf in the Ku band is requested.

An impedance at Δf in a case where an output side is seen from a transistor has a strong correlation with the IMD3 at Δf. Thus, in order to reduce the IMD3, it is effective to sufficiently reduce the impedance at Δf in the case where the output side is seen from the transistor.

In PTL 1, a wire and a line are connected to a main line of an output-side circuit. A capacitor having a capacitance for short-circuiting A is connected to a distal end of a circuit configured with the wire and the line. Accordingly, LC resonance can be obtained, the impedance at Δf can be reduced, and the IMD3 at Δf can be reduced. A plurality of such difference frequency short circuits by LC resonance are provided, and a wide detuning width can thereby be realized. However, it can be presumed that when a wire is attached to a main line in an MMIC for the Ka band, variation in the wire with respect to wavelengths in the Ka band cannot be ignored. Thus, the RF characteristics become sensitive about variation in the wire length, and a yield might thereby largely be lowered.

As difference frequency short-circuiting means different from the above case, connecting a capacitor for short-circuiting the difference frequency with the main line via a drain bias circuit can be raised. In this case, although plural kinds of capacitors can be used, as an inductor, only one kind of wire can be applied. Thus, only one resonance point is provided, and wide detuning characteristics cannot be obtained.

In order to provide more resonance points by an inductance, it is possible to provide a ¼ wavelength short stub as the inductance on an MMIC chip. However, even for the Ka band, a ¼ wavelength line is large relatively to a chip size. Thus, there is a problem that when plural short stubs are provided, the chip size increases and a manufacturing cost increases.

An object of the present disclosure is to obtain a power amplifier which enables size reduction.

### Solution to Problem

A power amplifier according to the present disclosure includes a transistor; a main line connected to a drain of the transistor; a branch line which branches from the main line and is connected to a drain pad; and a drain bias circuit which is provided on the branch line, wherein the drain bias circuit has a first shunt capacitor which is connected to the branch line and a second shunt capacitor which is connected to the branch line between the first shunt capacitor and the drain pad, the first shunt capacitor is capacitive at an operating frequency of the transistor, the second shunt capacitor is inductive at the operating frequency, and the first shunt capacitor and the second shunt capacitor resonate at the operating frequency.

### Advantageous Effects of Invention

In a power amplifier according to the present disclosure, a first shunt capacitor and a second shunt capacitor resonate. Thus, a short stub does not have to be used for a drain bias circuit, and size reduction of the power amplifier can be achieved.

### BRIEF DESCRIPTION OF DRAWINGS

FIG. 1 is a block diagram of a power amplifier according to a first embodiment.

FIG. 2 is a diagram illustrating a configuration of an output-side circuit of the final stage of the power amplifier according to the first embodiment.

FIG. 3 is a diagram illustrating a configuration of the capacitor circuit according to the first embodiment.

FIG. 4 is a diagram illustrating a layout of the capacitor circuit according to the first embodiment.

FIG. 5 is an equivalent circuit diagram of the capacitor circuit according to the first embodiment.

FIG. 6 is a diagram for explaining an ideal capacitor.

FIG. 7 is a diagram illustrating an impedance of the ideal capacitor.

FIG. 8 is an equivalent circuit diagram of the first shunt capacitor according to the first embodiment.

FIG. 9 is a diagram illustrating the impedance of the first shunt capacitor according to the first embodiment.

FIG. 10 is an equivalent circuit diagram of the second shunt capacitor according to the first embodiment.

FIG. 11 is a diagram illustrating the impedance of the second shunt capacitor according to the first embodiment.

FIG. 12 is an equivalent circuit diagram of the second shunt capacitor and the air bridge according to the first embodiment.

FIG. 13 is a diagram illustrating the impedance of the second shunt capacitor and the air bridge according to the first embodiment.

FIG. 14 is an equivalent circuit diagram of the capacitor circuit according to the first embodiment.

FIG. 15 is a diagram illustrating the impedance of the capacitor circuit according to the first embodiment.

FIG. 16 is a diagram illustrating a configuration of an output-side circuit of the final stage of the power amplifier according to a modification of the first embodiment.

FIG. 17 is a diagram illustrating a configuration of an output-side circuit of a final stage of a power amplifier according to a comparative example.

FIG. 18 is an equivalent circuit diagram of the MIM capacitor.

FIG. 19 is a diagram illustrating a layout of a MIM capacitor.

FIG. 20 is a diagram illustrating a layout of a MIM capacitor which has the same area as the MIM capacitor illustrated in FIG. 19.

FIG. 21 is a diagram illustrating the impedance of the MIM capacitor illustrated in FIG. 19.

FIG. 22 is a diagram illustrating the impedance of the MIM capacitor illustrated in FIG. 20.

FIG. 23 is a diagram illustrating C2/C1 dependency of the impedance of the capacitor circuit.

FIG. 24 is a diagram illustrating a layout of the capacitor circuit in a case where C2/C1=15.

FIG. 25 illustrates the layout of the capacitor circuit in a case where C2/C1=6.

FIG. 26 is a diagram illustrating a layout of a capacitor circuit according to a comparative example.

FIG. 27 is a cross-sectional view illustrating a state where the air bridge is connected to the first shunt capacitor according to the first embodiment.

FIG. 28 is a diagram illustrating a state where the chip capacitor is provided in the power amplifier according to the first embodiment.

FIG. 29 is a diagram illustrating a layout of a capacitor circuit according to a second embodiment.

FIG. 30 is a diagram illustrating a layout of a capacitor circuit according to a comparative example.

FIG. 31 is a diagram illustrating the impedance of the capacitor circuit according to the second embodiment.

FIG. 32 is a diagram illustrating the impedance of the capacitor circuit according to the comparative example.

### DESCRIPTION OF EMBODIMENTS

A power amplifier according to each embodiment will be described with reference to the drawings. Identical or corresponding constitutional elements are given the same reference numerals, and the repeated description of such constitutional elements may be omitted.

### First Embodiment

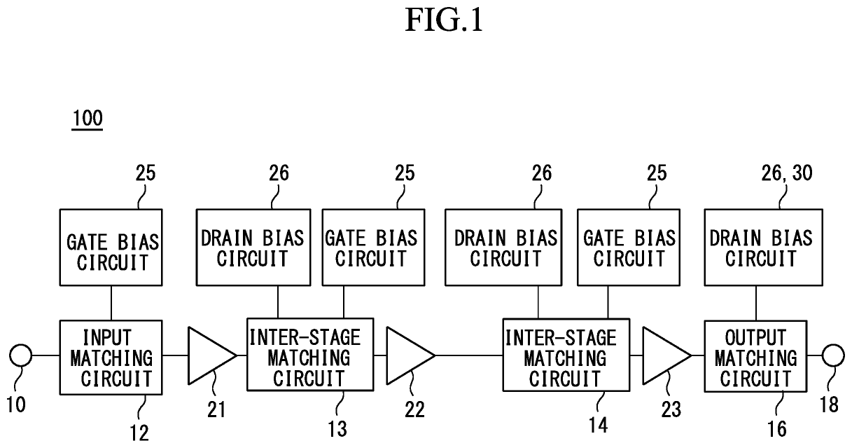

FIG. 1 is a block diagram of a power amplifier 100) according to a first embodiment. The power amplifier 100 includes three power amplification stages. Note that the number of power amplification stages is not limited to three. An input matching circuit 12 is connected between an input terminal 10 and a transistor 21 of a first stage. Inter-stage matching circuits 13 and 14 are respectively connected between the transistor 21 of the first stage and a transistor 22 of a second stage and between the transistor 22 of the second stage and a transistor 23 of a final stage. An output matching circuit 16 is connected between the transistor 23 of the final stage and an output terminal 18. A gate bias circuit 25 and a drain bias circuit 26 are provided in each of the stages.

An operating frequency of the power amplifier 100 corresponds to a Ka band. The power amplifier 100 is configured with one Ka-band MMIC chip, for example. As the transistors 21, 22, and 23, for example, GaN-based transistors optimal for a high-output amplifier are used. This is not restrictive, and GaAs-based or InP-based transistors or the like may be used. A substrate of an MMIC is formed of SiC, for example. Materials of the substrate may be different.

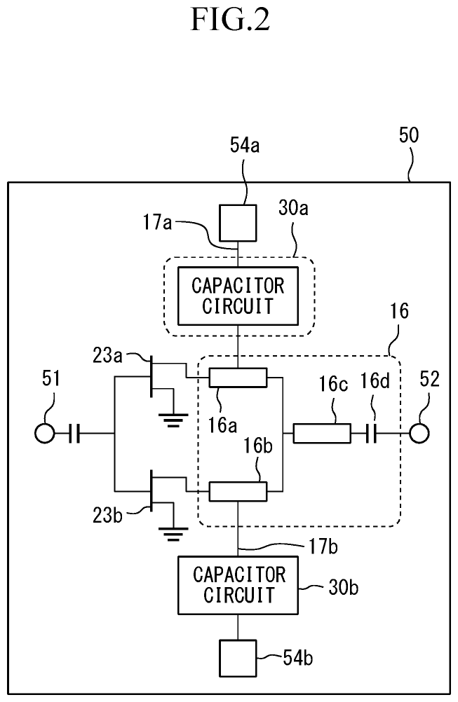

FIG. 2 is a diagram illustrating a configuration of an output-side circuit of the final stage of the power amplifier 100 according to the first embodiment. The first stage, the second stage, and an input-side circuit of the final stage are not illustrated. An MMIC chip 50 includes transistors 23a and 23b as the transistors 23. Gates of the transistors 23a and 23b are connected in parallel with an input terminal 51 via a capacitor. One ends of main lines 16a and 16b are connected to drains of the transistors 23a and 23b. One end of a main line 16c is connected to the other ends of the main lines 16a and 16b. An output terminal 52 is connected to the other end of the main line 16c via a coupling capacitor 16d. The output matching circuit 16 is configured with the main lines 16a. 16b, and 16c transmitting an RF output signal and the coupling capacitor 16d.

Next, a description will be made about a configuration of the drain bias circuit 26 of the final stage. The drain bias circuit 26 of the final stage is a capacitor circuit 30. Note that the drain bias circuits 26 of the first stage and the second stage may have the same configuration as that of the final stage or may have a different configuration. Branch lines 17a and 17b respectively branch from the main lines 16a and 16b. The branch lines 17a and 17b are respectively connected to drain pads 54a and 54b. The drain pads 54a and 54b will also be referred to as DC pads. On the branch lines 17a and 17b, as the capacitor circuits 30, capacitor circuits 30a and 30b are respectively provided.

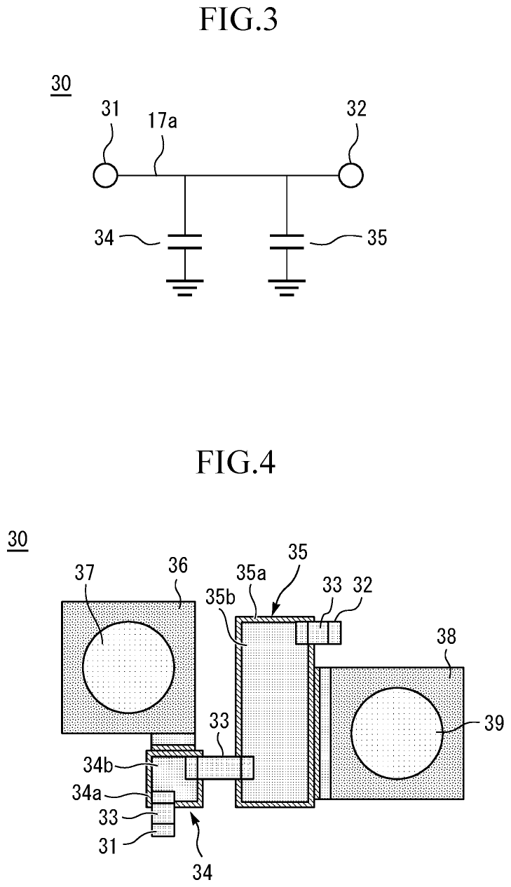

FIG. 3 is a diagram illustrating a configuration of the capacitor circuit 30 according to the first embodiment. In the following, a description will be made about the capacitor circuit 30a as an example, but the capacitor circuit 30b has a similar configuration. The capacitor circuit 30 has a terminal 31 which is connected to the main line 16a and a terminal 32 which is connected to the drain pad 54a. The capacitor circuit 30 has a first shunt capacitor 34 which is connected to the branch line 17a and a second shunt capacitor 35 which is connected to the branch line 17a between the first shunt capacitor 34 and the drain pad 54a.

FIG. 4 is a diagram illustrating a layout of the capacitor circuit 30 according to the first embodiment. The first shunt capacitor 34 and the second shunt capacitor 35 are MIM (metal-insulator-metal) capacitors, for example. The first shunt capacitor 34 has a lower base electrode 34a which is connected to grounding wiring and an upper base electrode 34b which is provided above the lower base electrode 34a. Similarly, the second shunt capacitor 35 has a lower base electrode 35a and an upper base electrode 35b which is provided above the lower base electrode 35a. Further, in each of the MIM capacitors, a MIM insulation film which is not illustrated is provided between the upper base electrode and the lower base electrode.

The upper base electrode 34b of the first shunt capacitor 34 is connected to the main line 16a via an air bridge 33. The lower base electrode 34a of the first shunt capacitor 34 is connected to a via hole 37 as grounding wiring via via-hole wiring 36. The upper base electrode 34b is connected to the upper base electrode 35b of the second shunt capacitor 35 via the air bridge 33. The lower base electrode 35a of the second shunt capacitor 35 is connected to a via hole 39 as grounding wiring via via-hole wiring 38. The upper base electrode 35b is connected to the drain pad 54a via the air bridge 33. The via holes 37 and 39 are connected to a ground which is provided on a substrate back surface. A DC bias is fed to the transistor 23a, which is connected to the main line 16a, via the drain pad 54a, the air bridge 33, and the upper base electrodes 35b and 34b.

The via holes 37 and 39 are formed by etching from the substrate back surface, for example. The via-hole wiring 36 and 38 serves as stoppers for etching. In FIG. 4, for convenience, the via holes 37 and 39 are illustrated. Actually, because the via-hole wiring 36 and 38 is present above the via holes 37 and 39, the via holes 37 and 39 cannot be seen.

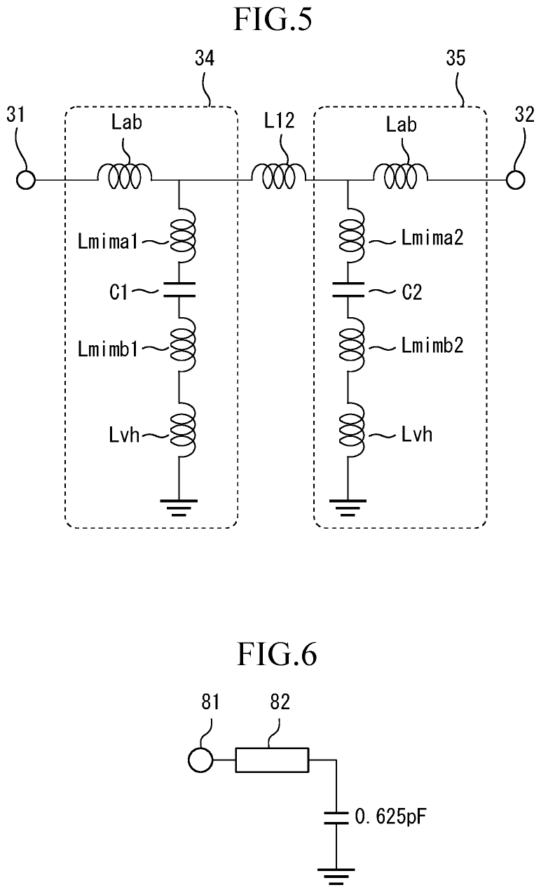

FIG. 5 is an equivalent circuit diagram of the capacitor circuit 30 according to the first embodiment. Capacitances of the first shunt capacitor 34 and the second shunt capacitor 35 are respectively denoted as C1 and C2. The MIM capacitor has a parasitic inductance. Here, the parasitic inductances of the upper base electrodes 34b and 35b are denoted as Lmima1 and Lmima2, the parasitic inductances of the lower base electrodes 34a and 35a are denoted as Lmimb1 and Lmimb2, and the parasitic inductance of the air bridge 33 is denoted as Lab.

Further, the inductance of a connection line between the first shunt capacitor 34 and the second shunt capacitor 35 is denoted as L 12, and the parasitic inductance of the via hole is denoted as Lvh.

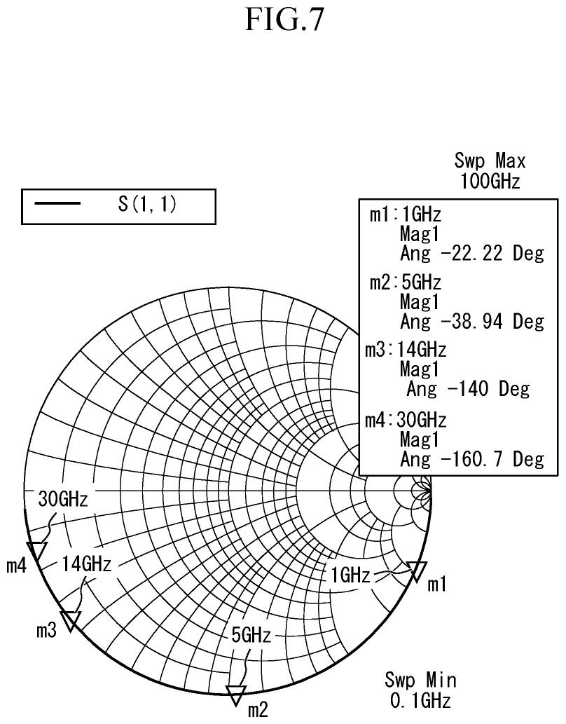

FIG. 6 is a diagram for explaining an ideal capacitor. The ideal capacitor has no parasitic component. One end of the ideal capacitor is connected to a terminal 81 via a phase adjustment line 82. The other end of the ideal capacitor is grounded. FIG. 7 is a diagram illustrating an impedance of the ideal capacitor. In FIG. 7, as examples of L, C. Ku, and Ka bands, markers are respectively given to 1 GHz, 5 GHz, 14 GHz, and 30 GHz. When an electrical length of the phase adjustment line 82 is set as 0°, the impedance in a case where the ideal capacitor is seen from the terminal 81 is capacitive at 1 GHz, 5 GHz, and 14 GHz. Meanwhile, at 30 GHz as the Ka band, the impedance is capacitive but is also close to an inductive impedance. Note that an upper half of the Smith chart represents inductive impedance, and a lower half represents a capacitive impedance.

In FIG. 7, in order to make the impedance at 14 GHz inductive, it is necessary to set the electrical length of the phase adjustment line 82 to 20°. In this case, when it is presumed that a microstrip line with a substrate thickness of 50 μm and a characteristic impedance of 50Ω is provided in a SiC substrate which is in general used for a GaN-based transistor, a line of about 480 μm is necessary. Meanwhile, in a case where the impedance at 30 GHz as the Ka band is made inductive, the electrical length of the phase adjustment line 82 may be set to 10°. This corresponds to a line of about 120 μm when it is presumed that the microstrip line with a substrate thickness of 50 μm and a characteristic impedance of 50Ω is similarly provided in the SiC substrate. As described above, a physical length necessary for obtaining inductivity in the Ka band is ¼ compared to that in the Ku band.

The parasitic inductances are present in the actual MIM capacitor and via hole. In the present embodiment, the second shunt capacitor 35 is made inductive by utilizing the parasitic inductances. An intrinsic capacitance of the MIM capacitor is denoted as Cint, the parasitic inductances of the MIM capacitor and the via hole are denoted as Lext, a phase of the intrinsic capacitance is denoted as Cint, and a phase of the parasitic inductance is denoted as ϕLext. In this case, an inductive capacitor can be obtained by Lext which satisfies ϕLext>1800+ϕCint (expression (1)).

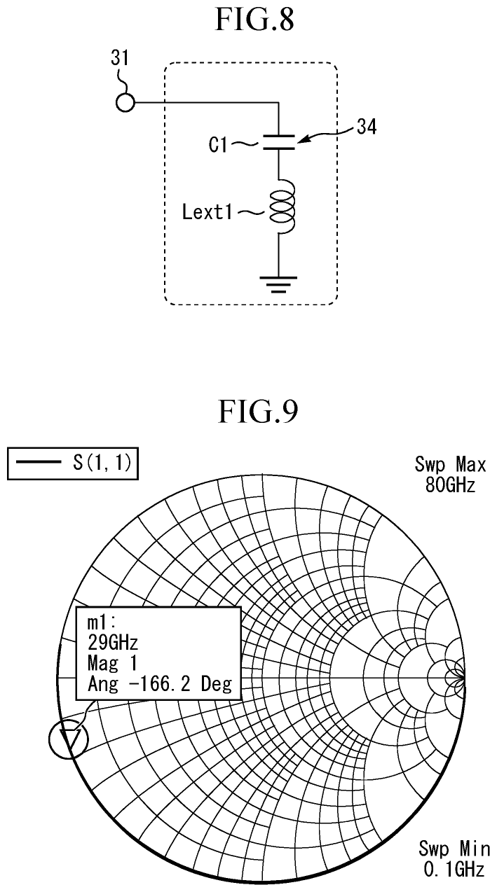

FIGS. 8 to 15 illustrate equivalent circuits and the impedances of the MIM capacitor as a single body or the capacitor circuit 30. The Smith charts illustrated in FIGS. 9, 11, 13, and 15 illustrate the impedances of the MIM capacitor or the capacitor circuit 30, which is seen from the terminal 31. In FIGS. 9, 11, 13, and 15, markers are given to 29 GHz. Another end of the MIM capacitor is connected to the ground on the substrate back surface via the via hole. Here, for convenience, the parasitic inductances of the MIM capacitor and the via hole are collectively denoted as Lext1 and Lext2. The frequency is 29 GHz, C1=0.63 pF. C2=3.8 pF, Lext1=15 pH, Lext2=23 pH, and L12=18 pH.

FIG. 8 is an equivalent circuit diagram of the first shunt capacitor 34 according to the first embodiment. FIG. 9 is a diagram illustrating the impedance of the first shunt capacitor 34 according to the first embodiment. The first shunt capacitor 34 is a small-sized MIM capacitor which is capacitive while including the parasitic inductance.

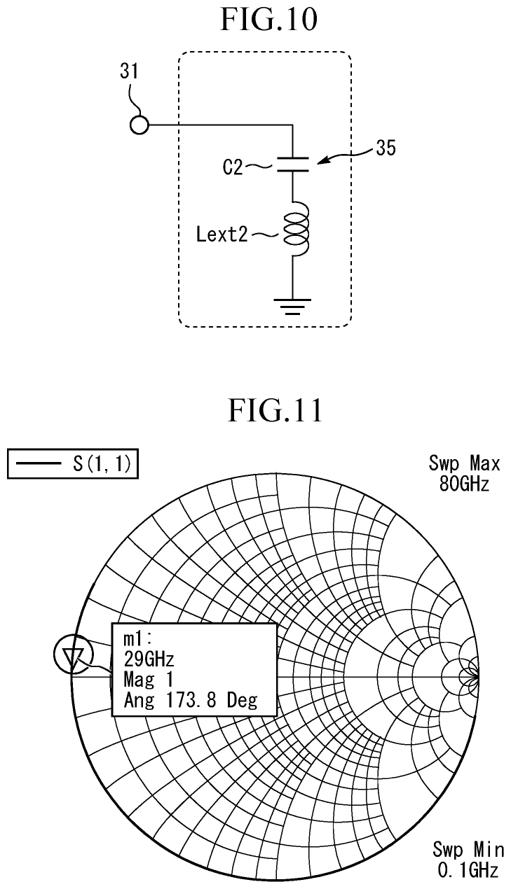

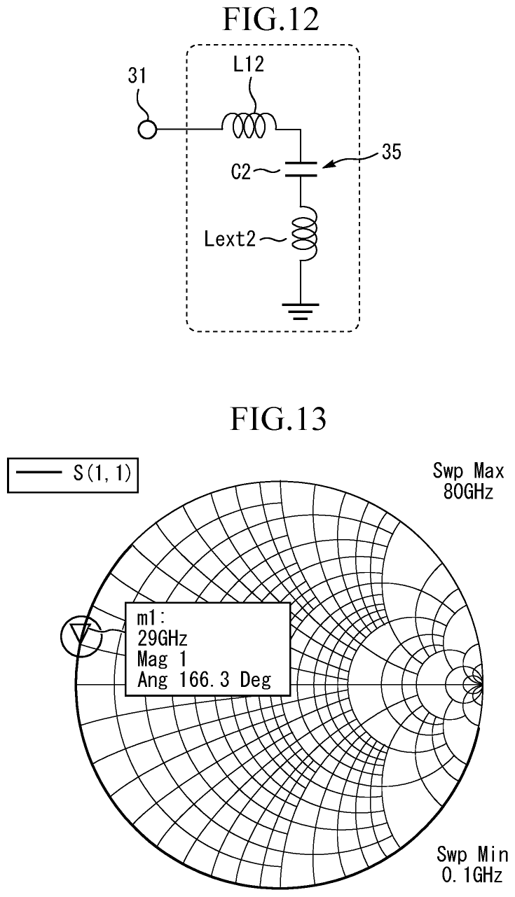

FIG. 10 is an equivalent circuit diagram of the second shunt capacitor 35 according to the first embodiment. FIG. 11 is a diagram illustrating the impedance of the second shunt capacitor 35 according to the first embodiment. FIG. 12 is an equivalent circuit diagram of the second shunt capacitor 35 and the air bridge 33 according to the first embodiment. FIG. 13 is a diagram illustrating the impedance of the second shunt capacitor 35 and the air bridge 33 according to the first embodiment. In FIG. 12, the inductance of the air bridge 33 is denoted as L12. The second shunt capacitor 35 is formed as a large-sized MIM capacitor such that it satisfies the expression (1) while including the parasitic inductance and becomes inductive.

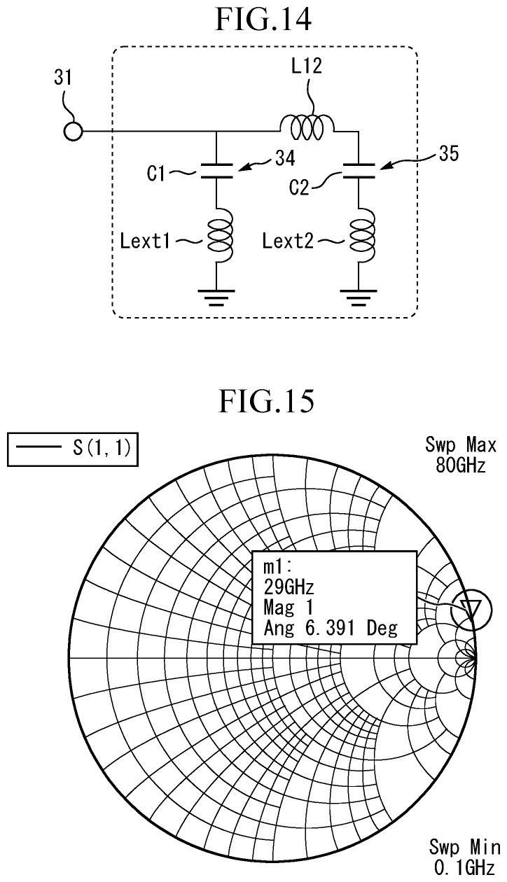

FIG. 14 is an equivalent circuit diagram of the capacitor circuit 30 according to the first embodiment. FIG. 15 is a diagram illustrating the impedance of the capacitor circuit 30 according to the first embodiment. When the first shunt capacitor 34 which is capacitive and second software which is inductive are connected together by the air bridge 33. LC parallel resonance occurs. In this case, as illustrated in FIG. 15, the capacitor circuit 30 has a high impedance. Because the impedance is high, an influence of the capacitor circuit 30 on characteristics of a main circuit can be suppressed.

In the capacitor circuit 30 of the present embodiment, the first shunt capacitor 34 is capacitive at an operating frequency of the transistor 23a, and the second shunt capacitor 35 is inductive at the operating frequency of the transistor 23a. At the operating frequency of the transistor 23a, the first shunt capacitor 34 and the second shunt capacitor 35 resonate. A difference frequency short circuit can be configured by connecting a capacitor for short-circuiting a difference frequency with the capacitor circuit 30 via the drain pad 54a. In the present embodiment, a ¼ wavelength short stub as a drain bias circuit does not have to be added. Thus, size reduction of the power amplifier 100 can be achieved. Further, a chip cost can be reduced.

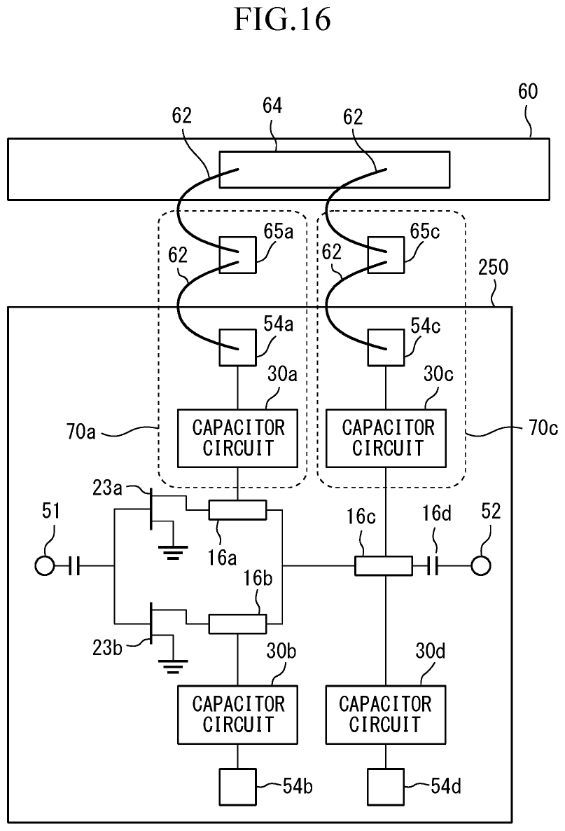

FIG. 16 is a diagram illustrating a configuration of an output-side circuit of the final stage of the power amplifier 100 according to a modification of the first embodiment. An MMIC chip 250 is different from the MMIC chip 50 in the point that the MMIC chip 250 further includes capacitor circuits 30c and 30d and drain pads 54c and 54d. Plural branch lines branch from the main lines 16a and 16c, and plural capacitor circuits 30a and 30c are provided on the plural branch lines. Configurations of the capacitor circuits 30c and 30d are similar to those of the capacitor circuits 30a and 30b.

The drain pads 54a and 54c are connected to upper electrodes of chip capacitors 65a and 65c which are provided on the outside of a chip via wires 62. The chip capacitors 65a and 65c have upper and lower electrode structures. Lower electrodes of the chip capacitors 65a and 65c are connected to the ground. Each of the chip capacitors 65a and 65c is the capacitor for short-circuiting the difference frequency. In addition, the upper electrodes of the chip capacitors 65a and 65c are connected to a pad 64 which is provided on an outside-chip substrate 60 via the wires 62. The DC bias to be supplied to the drain of the transistor 23a is supplied from the pad 64.

The chip capacitor 65a, the wires 62, the drain pad 54a, and the capacitor circuit 30a configure a difference frequency short circuit 70a. Similarly, the chip capacitor 65c, the wires 62, the drain pad 54c, and the capacitor circuit 30c configure a difference frequency short circuit 70c. Although not illustrated, configurations of chip capacitors and an outside-chip substrate which are connected to the capacitor circuits 30b and 30d are similar to configurations of the chip capacitors 65a and 65c and the outside-chip substrate 60.

As described above, because size reduction of the difference frequency short circuits 70a and 70c can be achieved in the present embodiment, plural difference frequency short circuits 70a and 70c can be provided. Consequently, resonance points for the number of difference frequency short circuits 70a and 70b can be provided, and a wide detuning width becomes possible. In FIG. 16, two difference frequency short circuits 70a and 70b are provided for one transistor 23a, but it is sufficient that the number of different frequency short circuits is one or more.

Note that the wires 62 are used in FIG. 16, but because a main signal is short-circuited by the capacitor circuit 30, the wires 62 do not influence the main signal.

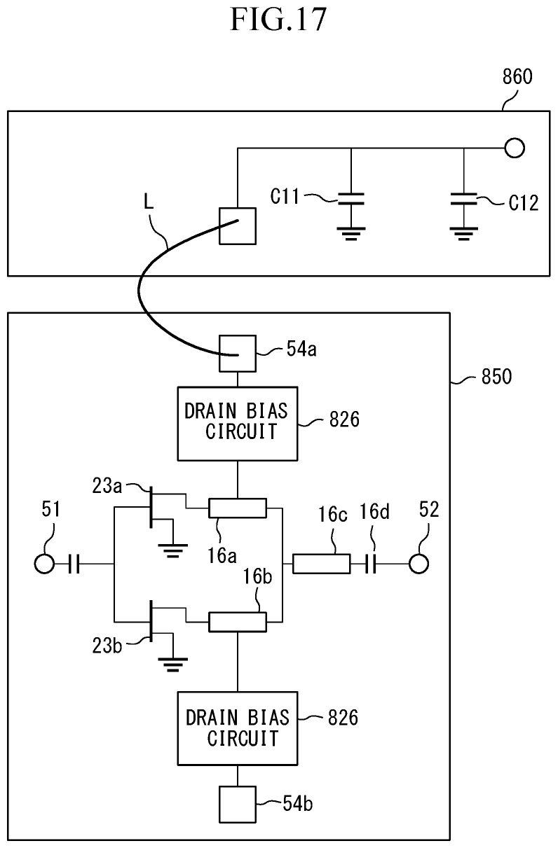

FIG. 17 is a diagram illustrating a configuration of an output-side circuit of a final stage of a power amplifier according to a comparative example. An MMIC chip 850 according to the comparative example includes drain bias circuits 826. The drain bias circuit 826 is connected to chip capacitors C11 and C12, which are provided on an outside-chip substrate 860, via the drain pad 54a and a wire L. Each of the chip capacitors C11 and C12 is the capacitor for short-circuiting the difference frequency. In the comparative example, plural kinds of chip capacitors C11 and C12 can be used. However, only one kind of wire L as an inductor can be applied. Thus, only L(C11+C12) resonance can be obtained, and wide detuning characteristics cannot be obtained. On the other hand, in the present embodiment, a wide detuning width becomes possible by providing plural small-sized difference frequency short circuits 70a and 70c.

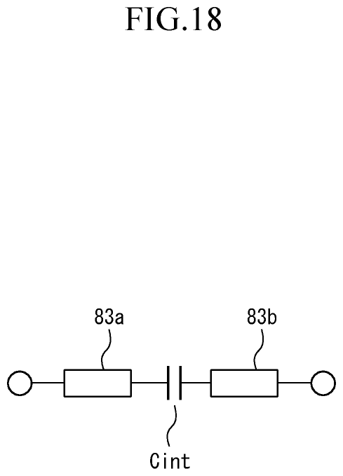

Next, a description will be made about a MIM capacitor which is likely to exhibit inductivity and a MIM capacitor which is less likely to exhibit inductivity. FIG. 18 is an equivalent circuit diagram of the MIM capacitor. An equivalent circuit of the MIM capacitor is represented by the intrinsic capacitance Cint and distributed constant lines 83a and 83b as the parasitic inductances. The intrinsic capacitance Cint is a parallel plate capacitance. Thus, the intrinsic capacitance Cint is defined by a thickness of an insulation film, relative permittivity of the insulation film, and an electrode size. As for each of the distributed constant lines 83a and 83b as parasitic components, a width is the same as a capacitor width, a length is set to ½ of a length of the capacitor, and the parasitic inductance Lext can be obtained.

In a case where a capacitance value of the MIM capacitor is 3.8 pF, for example, and is large, a capacitor size is large, and the parasitic inductance is also large. In this case, in a case where the MIM capacitor has a square shape having one side of 153 μm, inductivity can be obtained. Here, the thickness of the insulation film of the MIM capacitor is set to 350 nm, and the relative permittivity is set to 6.4. Further, as for each of the distributed constant lines 83a and 83b, a substrate material is SiC, a substrate thickness is set to 50 μm, and a wiring thickness is set to 2 μm. As described above, when the capacitance value is large, inductivity is likely to be obtained. However, when the capacitance value is small, inductivity is less likely to be obtained.

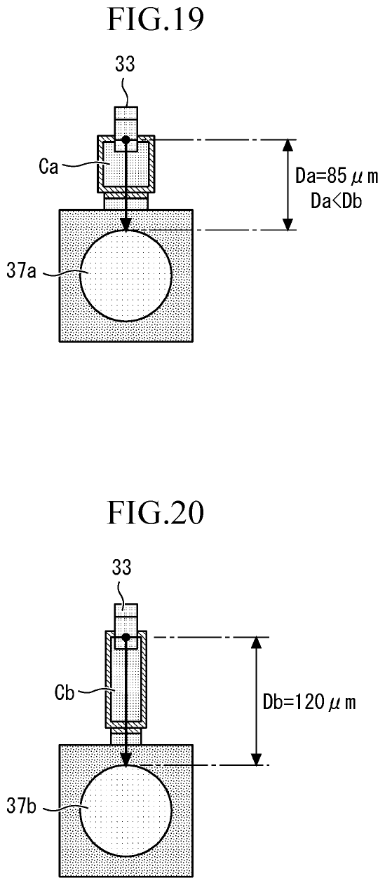

In order to make a capacitor with a small capacitance value be inductive, a layout is effective in which a shape from an input end of the MIM capacitor to the via hole is thin and long such that L components of the distributed constant lines 83a and 83b are made large. FIG. 19 is a diagram illustrating a layout of a MIM capacitor Ca. FIG. 20 is a diagram illustrating a layout of a MIM capacitor Cb which has the same area as the MIM capacitor Ca illustrated in FIG. 19. The MIM capacitor Ca has a square shape in a planar view, and the MIM capacitor Cb has a rectangular shape in a planar view. Both of the areas of the MIM capacitors Ca and Cb are 2,100 μm², and both of their capacitance values are 0.34 pF and are small.

Input ends are set as end portions, which overlap the air bridge 33, of upper base electrodes of the MIM capacitors Ca and Cb. As for distances from the input ends to via holes 37a and 37b, the distance in the MIM capacitor Ca is Da=85 μm, and the distance in the MIM capacitor Cb is Db=120 μm. In the MIM capacitor Cb, the parasitic inductance is increased by making Db long.

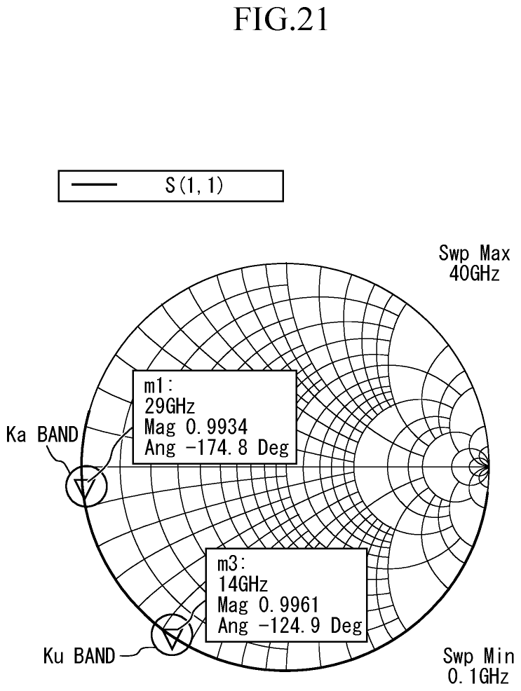

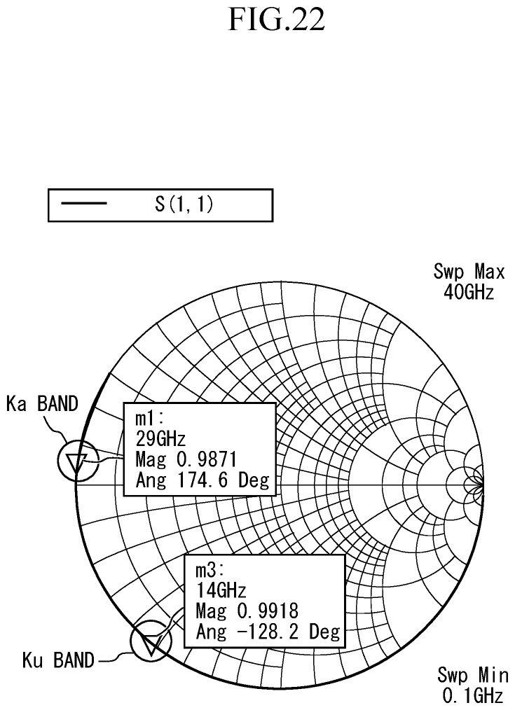

FIG. 21 is a diagram illustrating the impedance of the MIM capacitor Ca illustrated in FIG. 19. FIG. 22 is a diagram illustrating the impedance of the MIM capacitor Cb illustrated in FIG. 20. Although the MIM capacitors Ca and Cb have the same capacitance and the same area, in the Ka band, the MIM capacitor Ca having the square shape is capacitive, and the MIM capacitor Cb having the thin and long shape is inductive. Note that in the Ku band, neither of the MIM capacitors Ca and Cb exhibits inductivity only with the parasitic inductance, and both of those are capacitive. As described above, in the present embodiment, the upper base electrode 35b of the second shunt capacitor 35 is caused to have a rectangular shape in a planar view, and the second shunt capacitor 35 can thereby be set inductive while suppressing an area increase.

Note that the via holes 37a and 37b also have the parasitic inductances. Thus, in order to make the MIM capacitor inductive, the inductances of the via holes 37a and 37b can also be used. As described above, a setting is made such that the expression (1) is satisfied while including the parasitic inductance which the MIM capacitor has and the parasitic inductances of the via holes. Accordingly, in a millimeter-wave band which is equivalent to or higher than the Ka band, inductivity can be obtained in the shunt capacitor.

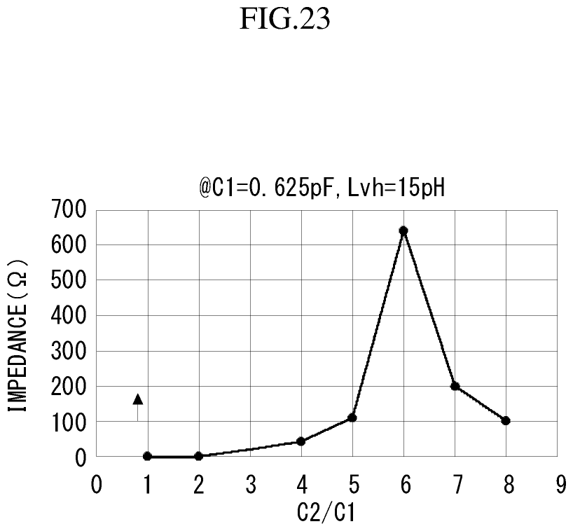

Next, a capacitance ratio C2/C1 between the first shunt capacitor 34 and the second shunt capacitor 35 will be discussed. FIG. 23 is a diagram illustrating C2/C1 dependency of the impedance of the capacitor circuit 30. Here, C1 is set to 0.625 pF. In FIG. 23, at C2/C1=5 to 8, a high impedance of 100Ω or higher can be obtained. Further, the impedance has a peak at C2/C1=6. This peak position depends on the value of C1. For example, in a case where C1=0.28 pF, the impedance has the peak at C2/C1=15.

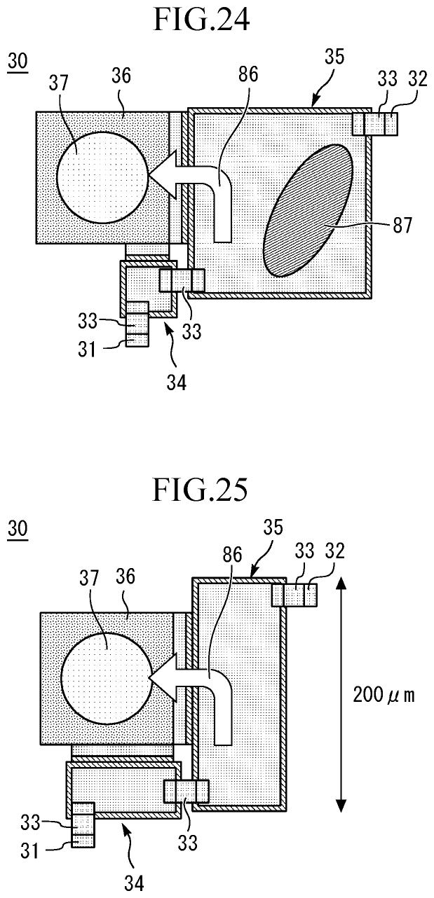

Next, a layout of the capacitor circuit will be discussed. FIG. 24 is a diagram illustrating a layout of the capacitor circuit 30 in a case where C2/C1=15. Here. C1=0.28 pF. For size reduction, only one via hole 37 is provided and is shared by the first shunt capacitor 34 and the second shunt capacitor 35. The first shunt capacitor 34 and the second shunt capacitor 35 are connected to adjacent sides of the via-hole wiring 36 having a rectangular shape. An arrow 86 indicates a path of a millimeter wave. In a case where C2/C1=15, because the size of the second shunt capacitor 35 is too large, a partial region 87 of the capacitance C2 does not seem to be a capacitance in the millimeter-wave band. In order to cause whole of the capacitance C2 to seem to be a capacitance, a via hole has to be added. In this case, in addition to the fact that the size of the second shunt capacitor 35 is large, the number of via holes becomes large. Consequently, a layout size might become large.

For comparison. FIG. 25 illustrates the layout of the capacitor circuit 30 in a case where C2/C1=6. Similarly to the case where C2/C1=15, the layout has arrangement for aiming at size reduction. Here, an initial value of the first shunt capacitor is 0.625 pF, but because the size of the first shunt capacitor is larger than that in FIG. 24 and the parasitic inductance becomes larger, the capacitance C1 becomes C1=0.38 pF and can be made smaller than the initial value. As in FIG. 25, in an example where C2/C1=6, the area of the second shunt capacitor is small, and the area which is expected to serve as a capacitance seems to be a capacitance.

Consequently, a small layout size can be realized. Note that in a case where C2/C1=15 and a pattern shape of the second shunt capacitor 35 is formed into an L shape, a portion which seems to be a capacitance increases. However, in this case also, compared to the case where C2/C1=6, the layout size becomes large. In the Ka band, when at least C2/C1≤8, a size increase of the chip can be suppressed.

By making C1 larger, the peak position in FIG. 23 may be shifted to a side where C2/C1 is lower. Here, C2/C1≥1. In general, when the capacitor is arranged on a side closer to the transistor as the capacitance is lower, an operation of the capacitor can further be stabilized. In a case where undesired oscillation occurs, as the frequency of an undesired wave becomes higher, coupling with another circuit more easily occurs. Thus, as the frequency becomes higher, it is desirable to short-circuit the undesired wave at a part closer to the transistor. A condition of the capacitor for short-circuiting the undesired wave is that impedance Z=1/(2πfC)≈0. As the frequency of the undesired wave becomes higher, the capacitor for short-circuiting the undesired wave becomes smaller. Thus, it is preferable that the capacitor having a lower capacitance be closer to the transistor, and it is desirable that C2/C1≥1.

Because of the above reasons, it is desirable that 1≤C2/C1≤8. In other words, it is desirable that the area of the upper base electrode 35b of the second shunt capacitor 35 be one to eight times the area of the upper base electrode 34b of the first shunt capacitor 34.

Further, when C1 is too small. C2/C1 becomes large, and a size increase of the layout might occur. Specifically, in a case where C1 is smaller than 0.3 pF, C2/C1 becomes large, and a size increase of the layout occurs. Further, when C1 is larger than 0.7 pF, the first shunt capacitor 34 which has to be capacitive by the parasitic inductance becomes inductive in the millimeter-wave band. Because of the above reasons, it is desirable that the capacitance of the first shunt capacitor 34 be 0.3 to 0.7 pF.

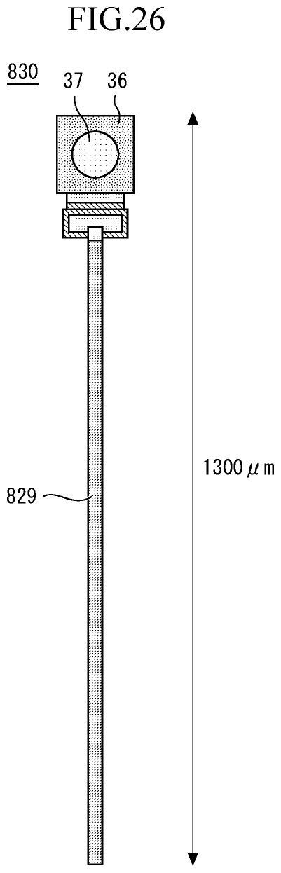

A vertical width of the capacitor circuit 30 illustrated in FIG. 25 is 200 μm. FIG. 26 is a diagram illustrating a layout of a capacitor circuit 830 according to a comparative example. In the capacitor circuit 830, the same function as the present embodiment is realized by using a ¼ wavelength short stub 829, the MIM capacitor, and the via hole 37. A vertical width of the capacitor circuit 830 according to the comparative example is about 1,300 μm. It can be understood that in the capacitor circuit 30 of the present embodiment, significant size reduction is possible compared to the comparative example.

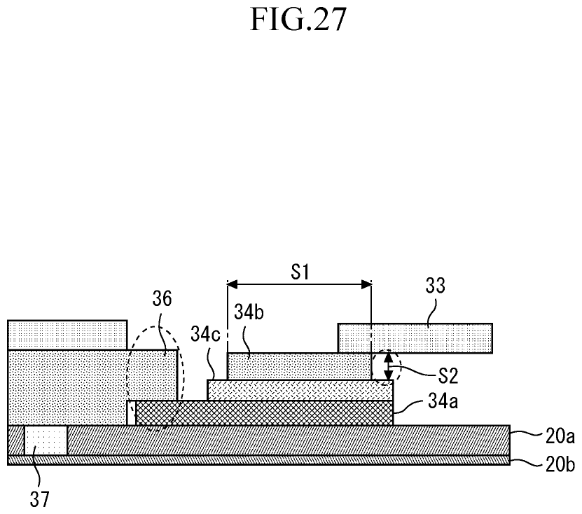

In the present embodiment, wiring which is connected to the upper base electrode 34b of the first shunt capacitor 34 or the upper base electrode 35b of the second shunt capacitor 35 includes the air bridge 33. FIG. 27 is a cross-sectional view illustrating a state where the air bridge 33 is connected to the first shunt capacitor 34 according to the first embodiment. The lower base electrode 34a is larger than the upper base electrode 34b. For example, in a case where the upper base electrode 34b is extended and used as wiring without using the air bridge 33, a portion where the upper base electrode 34b overlaps the lower base electrode 34a increases compared to an original area S1, and a parasitic capacitance might become large. On the other hand, when the air bridge 33 is used, a space S2 is provided between the air bridge 33 and a MIM insulation film 34c. Consequently, an increase in an unnecessary parasitic capacitance can be suppressed.

Further, the via-hole wiring 36 is used for connection between the lower base electrode 34a and the grounding wiring. Accordingly, a distance from the lower base electrode 34a to a back surface electrode can be minimized. Consequently, the unnecessary parasitic inductance can be suppressed.

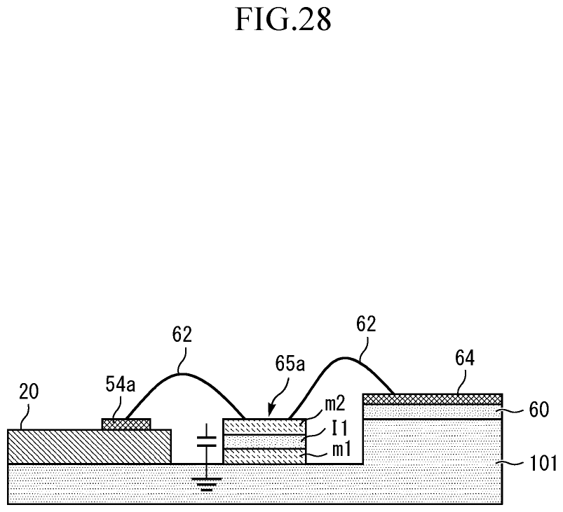

FIG. 28 is a diagram illustrating a state where the chip capacitor 65a is provided in the power amplifier 100 according to the first embodiment. In the power amplifier 100, a semiconductor substrate 20 as a substrate of the MMIC chip 50, the chip capacitors 65a and 65c, and the outside-chip substrate 60 are installed on a base 101 of a package. The base 101 corresponds to a ground potential. The outside-chip substrate 60 is formed of an insulator. In each of the chip capacitors 65a and 65c, a lower electrode m1, an insulator I1, and an upper electrode m2 are laminated. The lower electrode m1 is connected to the base 101. The chip capacitors 65a and 65c are connected to GND only by being mounted on the base 101. Consequently, a structure of the power amplifier 100 can be simplified, and assembly can be made easy. Note that the chip capacitors 65a and 65c may be substituted by barrel-shaped capacitors or the like.

Structures of portions of the power amplifier 100, layouts, and numerical values, which are described above, are examples, and those are not restrictive. Further, the capacitances and shapes of the shunt capacitors are not limited to those described above. It is sufficient that at the operating frequency, the first shunt capacitor 34 is capacitive, the second shunt capacitor 35 is inductive, and the first shunt capacitor and the second shunt capacitor resonate. Further, the present embodiment can also be applied to a frequency converter which uses the difference frequency short circuit or a switch which uses the drain bias circuit.

These modifications can be applied, as appropriate, to a power amplifier according to the following embodiment. Note that the power amplifier according to the following embodiment is similar to that of the first embodiment in many respects, and thus differences between the power amplifier according to the following embodiment and that of the first embodiment will be mainly described below.

### Second Embodiment

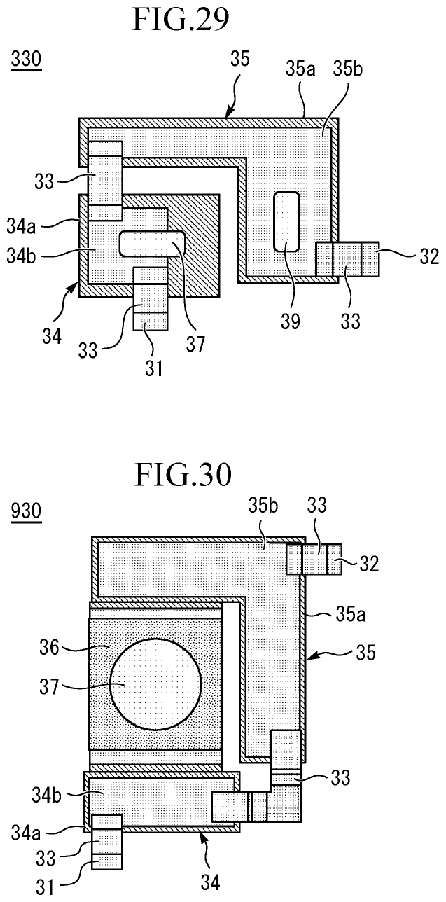

FIG. 29 is a diagram illustrating a layout of a capacitor circuit 330 according to a second embodiment. The first shunt capacitor 34 and the second shunt capacitor 35 are provided on the via holes 37 and 39. Other configurations are similar to configurations of the first embodiment.

FIG. 30 is a diagram illustrating a layout of a capacitor circuit 930 according to a comparative example. In the comparative example, the first shunt capacitor 34 and the second shunt capacitor 35 do not overlap the via hole 37. Note that in the capacitor circuit 930, for size reduction, the via hole 37 is shared by the first shunt capacitor 34 and the second shunt capacitor 35.

In both of the capacitor circuits 330 and 930. C1=0.40 pF, and C2=1.2 pF. In the capacitor circuit 330, because the via holes 37 and 39 are present directly below the first shunt capacitor 34 and the second shunt capacitor 35, the first shunt capacitor 34 and the second shunt capacitor 35 can also serve as via-hole wiring. Consequently, a layout area can be reduced by about 28% compared to the comparative example.

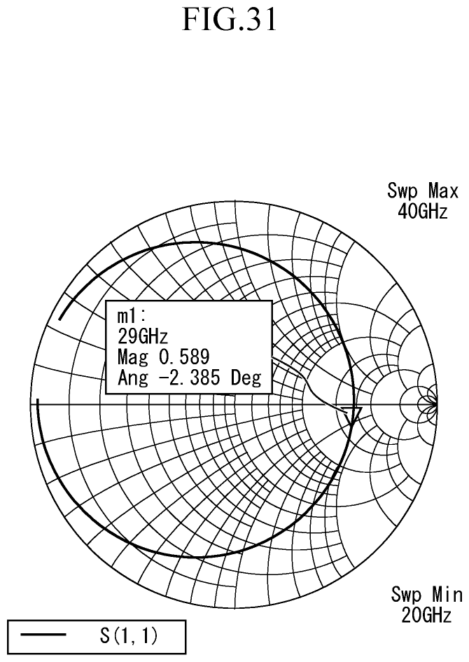

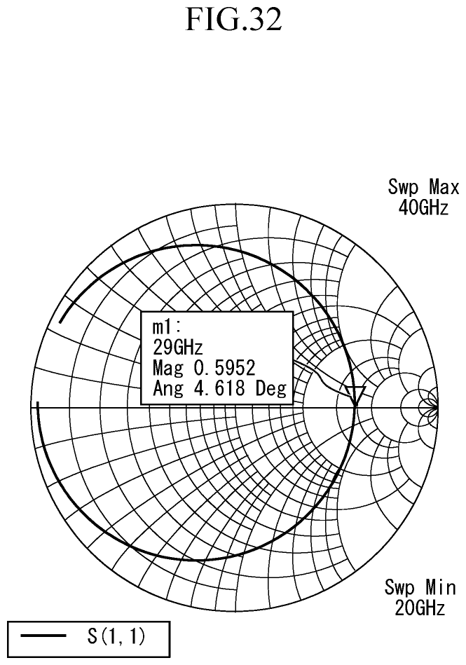

FIG. 31 is a diagram illustrating the impedance of the capacitor circuit 330 according to the second embodiment. FIG. 32 is a diagram illustrating the impedance of the capacitor circuit 930 according to the comparative example. FIGS. 31 and 32 illustrate the impedances obtained by an electromagnetic field analysis. Although the capacitor circuit 330 has a small size, the capacitor circuit 330 can realize an impedance equivalent to that of the capacitor circuit 930.

As a modification of the present embodiment, one of the first shunt capacitor 34 and the second shunt capacitor 35 may be provided above the via hole.

Note that the technical features described in the above embodiments may be combined as appropriate.

### REFERENCE SIGNS LIST

10 input terminal, 12 input matching circuit, 13 inter-stage matching circuit, 16 output matching circuit, 16a, 16b, 16c main line, 16d coupling capacitor, 17a branch line, 18 output terminal, 20 semiconductor substrate, 21, 22, 23, 23a, 23b transistor, 25 gate bias circuit, 26 drain bias circuit, 30, 30a, 30b, 30c capacitor circuit, 31, 32 terminal, 33 air bridge, 34 first shunt capacitor, 34a lower base electrode, 34b upper base electrode, 34c MIM insulation film, 35 second shunt capacitor, 35a lower base electrode, 35b upper base electrode, 36 via-hole wiring, 37, 37a via hole, 38 via-hole wiring, 39 via-hole, 50 MMIC chip, 51 input terminal, 52 output terminal, 54a, 54c drain pad, 60 outside-chip substrate, 62 wire, 64 pad, 65a, 65c chip capacitor, 70a, 70c difference frequency short circuit, 81 terminal, 82 phase adjustment line, 83a, 83b distributed constant line, 100 power amplifier, 101 base, 250 MMIC chip, 330 capacitor circuit, 826 drain bias circuit, 829 wavelength short stub, 830 capacitor circuit, 850 MMIC chip, 860 outside-chip substrate, 930 capacitor circuit, C11, C12 chip capacitor, Ca, Cb MIM capacitor, I1 insulator, L wire, m1 lower electrode, m2 upper electrode

1. A power amplifier comprising:
a transistor;
a main line connected to a drain of the transistor;
a branch line which branches from the main line and is connected to a drain pad; and
a drain bias circuit which is provided on the branch line, wherein
the drain bias circuit has
a first shunt capacitor which is connected to the branch line and
a second shunt capacitor which is connected to the branch line between the first shunt capacitor and the drain pad,
the first shunt capacitor is capacitive at an operating frequency of the transistor,
the second shunt capacitor is inductive at the operating frequency, and
the first shunt capacitor and the second shunt capacitor resonate at the operating frequency.

2. The amplifier according to claim 1, wherein each of the first shunt capacitor and the second shunt capacitor has a lower base electrode which is connected to grounding wiring and an upper base electrode which is provided above the lower base electrode.

3. The amplifier according to claim 2, wherein an area of the upper base electrode of the second shunt capacitor is one to eight times an area of the upper base electrode of the first shunt capacitor.

4. The amplifier according to claim 2, wherein the upper base electrode of the second shunt capacitor has a rectangular shape in a planar view.

5. The amplifier according to claim 2, wherein wiring which is connected to the upper base electrode of the first shunt capacitor or the upper base electrode of the second shunt capacitor includes an air bridge.

6. The amplifier according to claim 2, wherein the first shunt capacitor or the second shunt capacitor is provided on a via hole as the grounding wiring.

7. The amplifier according to claim 1, wherein a capacitance of the first shunt capacitor is 0.3 to 0.7 pF.

8. The amplifier according to claim 1, wherein the operating frequency corresponds to a Ka band.

9. The amplifier according to claim 1, wherein a plurality of the branch lines branch from the main line, and
a plurality of the drain bias circuits are provided on the plurality of the branch lines.
